(19) United States
(12) Patent Application Publication
(10) Pub. No.: US 2024/0088014 A1
(43) Pub. Date: Mar. 14, 2024

(54) DECOUPLING CAPACITOR ARCHITECTURE

(71) Applicant: QUALCOMM Incorporated, San Diego, CA (US)

(72) Inventors: Keyurkumar Karsanbhai KANSAGRA, Bangalore (IN); Manjanaika CHANDRANAIKA, Bangalore (IN); Ankit GUPTA, Lucknow (IN); Kamesh MEDISETTI, Bangalore (IN); Akhtar ALAM, Bangalore (IN)

(21) Appl. No.: 17/940,911

(22) Filed: Sep. 8, 2022

(51) Int. Cl. H01L 23/522; H01L 23/528

(52) U.S. Cl. CPC H01L 23/5223; H01L 23/5221; H01L 23/5286

(57) ABSTRACT

In certain aspects, a chip includes first source/drain contacts formed over a first oxide diffusion (OD), and first gates, wherein each of the first gates is disposed between a respective pair of the first source/drain contacts. The chip also includes a first bridge coupling a first one of the first source/drain contacts, a first one of the first gates, and a second one of the first source/drain contacts. The chip also includes a first metal routing coupled to the first one of the first source/drain contacts, and a second metal routing coupled to the second one of the first source/drain contacts.

### BACKGROUND

### Field

Aspects of the present disclosure relate generally to capacitors, and, more particularly, to capacitors integrated on a chip.

### Background

Capacitors may be integrated on a chip (i.e., die). Integrated capacitors may be used, for example, as decoupling capacitors. The decoupling capacitors may be used, for example, as charge storing devices to support instant current requirements in a power delivery network.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

An aspect relates to a chip. The chip includes first source/drain contacts formed over a first oxide diffusion (OD), and first gates, wherein each of the first gates is disposed between a respective pair of the first source/drain contacts. The chip also includes a first bridge coupling a first one of the first source/drain contacts, a first one of the first gates, and a second one of the first source/drain contacts. The chip also includes a first metal routing coupled to the first one of the first source/drain contacts, and a second metal routing coupled to the second one of the first source/drain contacts.

A second aspect relates to a chip. The chip includes a power rail, and a low rail, the low rail having a lower potential than the power rail. The chip also includes a decoupling capacitor coupled between the power rail and the low rail. The decoupling capacitor includes first source/drain contacts formed over a first oxide diffusion (OD), and first gates, wherein each of the first gates is disposed between a respective pair of the first source/drain contacts. The decoupling capacitor also includes a first bridge coupling a first one of the first source/drain contacts, a first one of the first gates, and a second one of the first source/drain contacts. The decoupling capacitor further includes a first metal routing coupled to the first one of the first source/drain contacts, and a second metal routing coupled to the second one of the first source/drain contacts, wherein the first metal routing and the second routing are coupled to the power rail.

### BRIEF DESCRIPTION OF THE DRAWINGS

FIG. 1 shows a side view of an example of a chip including metal layers and vias according to certain aspects of the present disclosure.

FIG. 2 shows an example of an n-type device according to certain aspects of the present disclosure.

FIG. 3 shows an example of a p-type device according to certain aspects of the present disclosure.

FIG. 4 shows an example of an n-type device and a p-type device according to certain aspects of the present disclosure.

FIG. 5 shows an example of a reversed biased diode formed using the n-type device and the p-type device, and the capacitance of the diode according to certain aspects of the present disclosure

FIG. 6A shows an example of gates, a first OD, and a second OD according to certain aspects of the present disclosure.

FIG. 6B shows an example of source/drain contacts according to certain aspects of the present disclosure.

FIG. 6C shows an example of a first bridge and a second bridge where each of the first and second bridges couples a respective gate to respective sources/drains according to certain aspects of the present disclosure.

FIG. 6D shows an example of vias disposed on source/drain contacts and gate contacts according to certain aspects of the present disclosure.

FIG. 6E shows an example of a layout including multiple n-type devices and multiple p-type devices forming a capacitor according to certain aspects of the present disclosure.

FIG. 7 shows a circuit diagram of an example of a decoupling capacitor according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

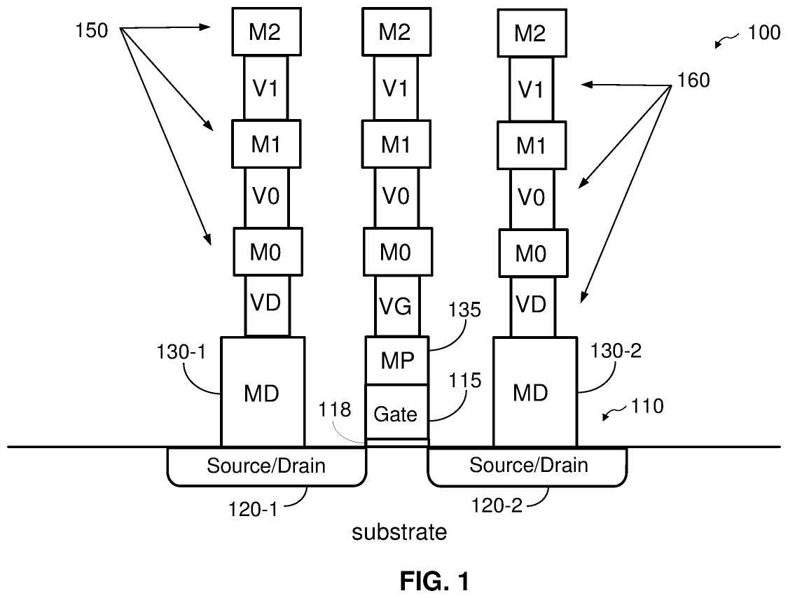

FIG. 1 shows a side view of an example of a chip 100 (i.e., die) according to certain aspects. The chip 100 may include many devices integrated on the chip 100. In this regard, FIG. 1 shows an example of a device 110 integrated on the chip 100. Although one device 110 is shown in FIG. 1 for simplicity, it is to be appreciated that the chip 100 may include many devices. The device 110 may be used as a transistor on the chip 100. The device 110 may also be used to form a capacitor (e.g., decoupling capacitor), as discussed further below.

In the example shown in FIG. 1, the device 110 includes a gate 115, a first source/drain 120-1, and a second source/drain 120-2. As used herein, the term “source/drain” means source and/or drain. The gate 115 is formed over a channel between the first source/drain 120-1 and the second source/drain 120-2. The device 110 may also include a thin gate oxide 118 between the gate 115 and the channel. The gate 115 may be a poly-silicon gate, a metal gate, or another type of gate. In the example shown in FIG. 1, the device 110 is depicted as a planar device. However, it is to be appreciated that the device 110 may be implemented using a fin field-effect transistor (FinFET) process.

The chip 100 may also includes a first source/drain contact 130-1 formed on the first source/drain 120-1, and a second source/drain contact 130-2 formed on the second source/drain 120-2. The source/drain contacts 130-1 and 130-2 may be formed from a source/drain contact layer (labeled “MD” in FIG. 1) using, for example, a lithographic process and an etching process. Although the source/drain contact layer is labeled “MD” in the example in FIG. 1, it is to be appreciated that the source/drain contact layer may also be labeled “CA” or another label. The source/drain contact layer may include one or more metals and/or one or more other electrically conductive materials.

The chip 100 may also include a gate contact 135 formed on the gate 115. The gate contact 135 may be formed from a gate contact layer (labeled “MP” in FIG. 1) using, for example, a lithographic process and an etching process. Although the gate contact layer is labeled “MP” in the example in FIG. 1, it is to be appreciated that the gate contact layer may also be labeled with another label. The gate contact layer may include one or more metals and/or one or more other electrically conductive materials.

The chip 100 may also include a stack of metal layers 150. The metal layers 150 are patterned (e.g., using lithography and etching) to provide metal routing for the device 110 and other devices (not shown) on the chip 100. The metal routing may be used, for example, to interconnect devices on the chip 100, couple devices to a power delivery network, couple devices to one or more input/output (I/O) pins, and the like. One or more metal layers may also be used to provide local routing within a device or cell. The metal layers 150 may also be referred to as metallization layers, or another term.

In the example in FIG. 1, the bottom-most metal layer may be designated metal layer M0 (also referred to as metal 0), the metal layer immediately above metal layer M0 may be designated metal layer M1 (also referred to as metal 1), the metal layer immediately above metal layer M1 may be designated metal layer M2 (also referred to as metal 2), and so forth. Although three metal layers are shown in FIG. 1 for ease of illustration, it is to be appreciated that the chip 100 may include additional metal layers (e.g., five or more metal layers including metal layer M3, metal layer M4, and so forth). It is to be appreciated that the present disclosure is not limited to the nomenclature in which the bottom-most metal layer is designated metal layer M0. For instance, in another example, the bottom-most metal layer may be designated metal layer M1 instead of metal layer M0.

The chip 100 also includes vias 160 that provide electrical coupling between the metal layers 150, and between metal layer M0 and the contacts 130-1, 130-2, and 135. In this example, the vias VD provide electrical coupling between the source/drain contacts 130-1 and 130-2 and metal layer M0, and the via VG provides electrical coupling between the gate contact 135 and metal layer M0. It is to be appreciated that vias VD and the via VG may be formed from the same via layer (e.g., using lithography and etching). The vias V0 provide electrical coupling between metal layer M0 and metal layer M1, and the vias V1 provide electrical coupling between metal layer M1 and metal layer M2.

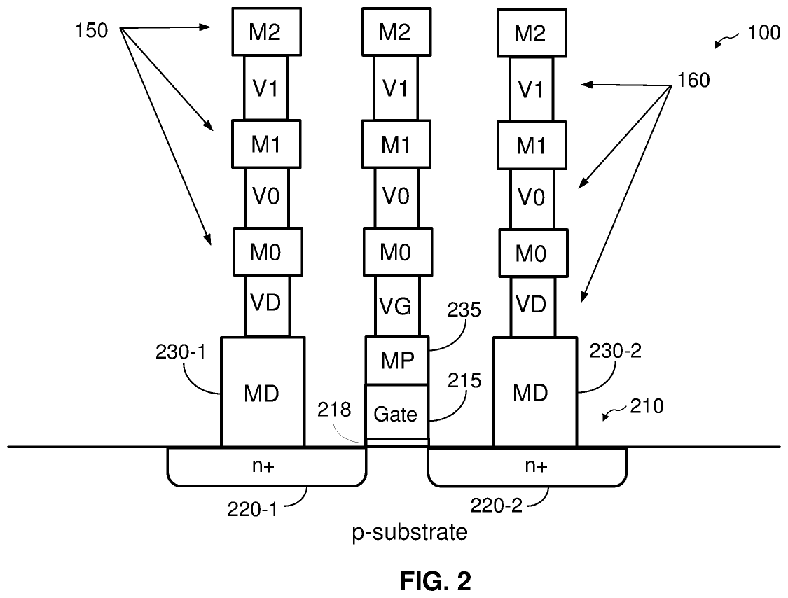

The device 110 shown in FIG. 1 may be used to implement an n-type device (e.g., n-type field effect transistor (NFET)) or a p-type device (e.g., p-type field effect transistor (PFET)). In this regard. FIG. 2 shows an example of an n-type device 210 implementation of the device 110 according to certain aspects. Although one n-type device 210 is shown in FIG. 2 for simplicity, it is to be appreciated that the chip 100 may include multiple instances of the n-type device 210. It is also to be appreciated that the chip 100 may include p-type devices, as discussed further below.

In the example shown in FIG. 2, the n-type device 210 includes a gate 215, a first source/drain 220-1, and a second source/drain 220-2. The first source/drain 220-1 and the second source/drain 220-2 may be formed in a p-substrate (i.e., p-type substrate), as shown in FIG. 2. Also, each of the first source/drain 220-1 and the second source/drain 220-2 may be an n+ source/drain, which may be formed using n+ diffusion, n+ implantation, or another process. The gate 215 is formed over a channel between the first source/drain 220-1 and the second source/drain 220-2. The n-type device 210 may also include a thin gate oxide 218 between the gate 215 and the channel. The gate 215 may be a poly-silicon gate, a metal gate, or another type of gate. In the example shown in FIG. 2, the n-type device 210 is depicted as a planar device. However, it is to be appreciated that the n-type device 210 may be implemented using a fin field-effect transistor (FinFET) process.

The chip 100 may also include a first source/drain contact 230-1 formed on the first source/drain 220-1, and a second source/drain contact 230-2 formed on the second source/drain 220-2. The source/drain contacts 230-1 and 230-2 may be formed from the source/drain contact layer discussed above using, for example, a lithographic process and an etching process. The chip 100 may also include a gate contact 235 formed on the gate 215. The gate contact 235 may be formed from the gate contact layer discussed above using, for example, a lithographic process and an etching process. In certain aspects, the source/drain contact layer and the gate contact layer may be the same contact layer or different contact layers.

FIG. 2 also shows the stack of metal layers 150 (also referred to as a metal layer stack), which may be patterned (e.g., using lithography and etching) to provide metal routing for the n-type device 210 and other devices (not shown) on the chip 100, as discussed above. FIG. 2 also shows the vias 160, which provide electrical coupling between the metal layers 150, and between metal layer M0 and the contacts 230-1, 230-2, and 235, as discussed above.

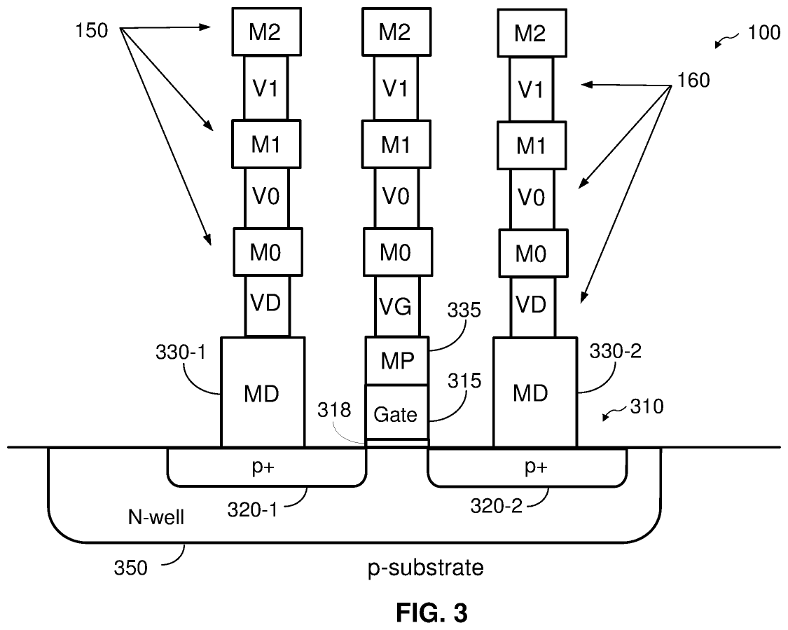

FIG. 3 shows an example of a p-type device 310 implementation of the device 110 according to certain aspects. Although one p-type device 310 is shown in FIG. 3 for simplicity, it is to be appreciated that the chip 100 may include multiple instances of the p-type device 310. It is also to be appreciated that the chip 100 may also include multiple instances of the n-type device 210 discussed above.

In the example shown in FIG. 3, the p-type device 310 includes a gate 315, a first source/drain 320-1, and a second source/drain 320-2. The first source/drain 320-1 and the second source/drain 320-2 may be formed in an N-well 350 in the p-substrate, as shown in FIG. 3. Also, each of the first source/drain 320-1 and the second source/drain 320-2 may be a p+ source/drain, which may be formed using p+ diffusion, p+ implantation, or another process. The gate 315 is formed over a channel between the first source/drain 320-1 and the second source/drain 320-2. The p-type device 310 may also include a thin gate oxide 318 between the gate 315 and the channel. The gate 315 may be a poly-silicon gate, a metal gate, or another type of gate. In the example shown in FIG. 3, the p-type device 310 is depicted as a planar device. However, it is to be appreciated that the p-type device 310 may be implemented using a fin field-effect transistor (FinFET) process.

The chip 100 may also include a first source/drain contact 330-1 formed on the first source/drain 320-1, and a second source/drain contact 330-2 formed on the second source/drain 320-2. The source/drain contacts 330-1 and 330-2 may be formed from the source/drain contact layer discussed above using, for example, a lithographic process and an etching process. The chip 100 may also include a gate contact 335 formed on the gate 315. The gate contact 335 may be formed from the gate contact layer discussed above using, for example, a lithographic process and an etching process. In certain aspects, the source/drain contact layer and the gate contact layer may be the same contact layer or different contact layers.

FIG. 3 also shows the stack of metal layers 150 (also referred to as a metal layer stack), which may be patterned (e.g., using lithography and etching) to provide metal routing for the p-type device 310 and other devices (not shown) on the chip 100, as discussed above. FIG. 3 also shows the vias 160, which provide electrical coupling between the metal layers 150, and between metal layer M0 and the contacts 330-1, 330-2, and 335, as discussed above.

The n-type device 210 and/or the p-type device 310 may be used to form a capacitor (e.g., decoupling capacitor) according to certain aspects. For example, a decoupling capacitor may be integrated on the chip 100 using one or more instances of the n-type device 210 and/or one or more instances of the p-type device 310.

Decoupling capacitors may be used, for example, as charge storing devices to support instant current requirements in a power delivery network. There may be various reasons for the instant current requirements. For example, a circuit receiving power from the power delivery network may draw a large transient current when the circuit is first powered on (e.g., due to charging of capacitors in the circuit). If there are no adequate measures to meet the instant current requirements, then large voltage droops or ground bounce may occur, which may cause functional failure of circuits (e.g., timing violations in logic devices). To support the instant current requirements of a power delivery network, decoupling capacitors may be inserted throughout the power delivery network.

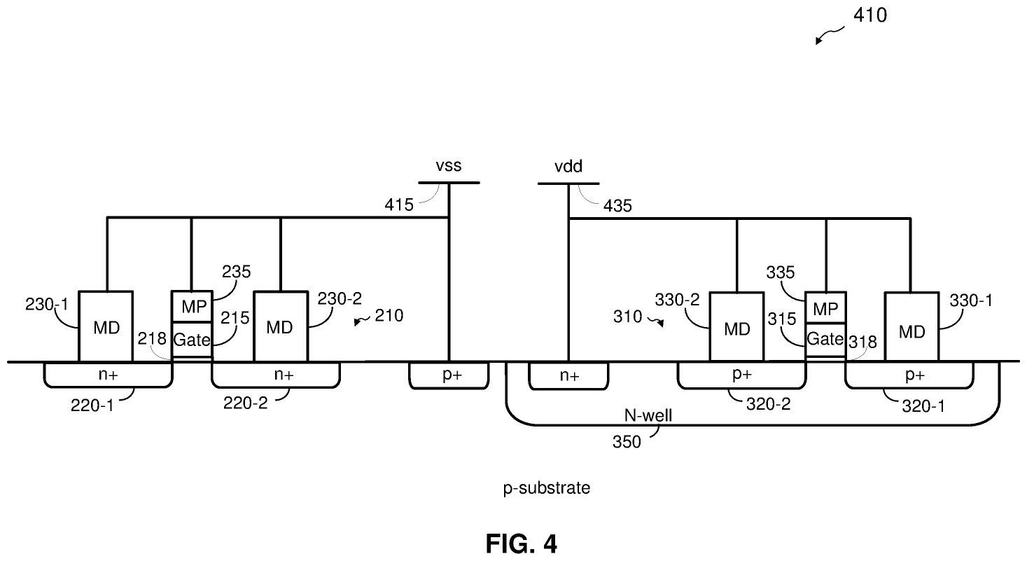

FIG. 4 shows an example in which the n-type device 210 and the p-type device 310 may be used to form a capacitor 410 (e.g., a decoupling capacitor) on the chip 100. Although one n-type device 210 and one p-type device 310 are shown in FIG. 4 for simplicity, it is to be understood that multiple n-type devices and/or multiple p-types devices may be used (e.g., to increase capacitance). In this example, the capacitor 410 is coupled between a power rail 435 and a low rail 415, and may be used as a decoupling capacitor. The power rail 435 (also referred to as a voltage supply rail) may provide power (e.g., supply voltage) to one or more circuits (not shown). The low rail 415 has a lower potential than the power rail 435. In one example, the low rail 415 is a ground rail coupled to ground, but is not limited to this example.

In the example in FIG. 4, the n-type device 210 and the p-type device 310 are next to one another on the chip 100. In this example, the gate 215, the first source/drain 220-1, and the second source/drain 220-2 of the n-type device 210 are coupled to one another and to the low rail 415 (e.g., ground rail). For example, the gate 215, the first source/drain 220-1, and the second source/drain 220-2 may be coupled to one another and to the low rail 415 through the contacts 230-1, 230-2, and 235, vias (e.g., VD and VG), and one or more of the metal layers 150. Note that the vias and the one or more of the metal layers 150 are not explicitly shown in FIG. 4 for ease of illustration.

Also, in this example, the gate 315, the first source/drain 320-1, and the second source/drain 320-2 of the p-type device 310 are coupled to one another and to the power rail 435. For example, the gate 315, the first source/drain 320-1, and the second source/drain 320-2 may be coupled to one another and to the power rail 435 through the contacts 330-1, 330-2, and 335, vias (e.g., VD and VG), and one or more of the metal layers 150. Note that the vias and the one or more of the metal layers 150 are not explicitly shown in FIG. 4 for ease of illustration.

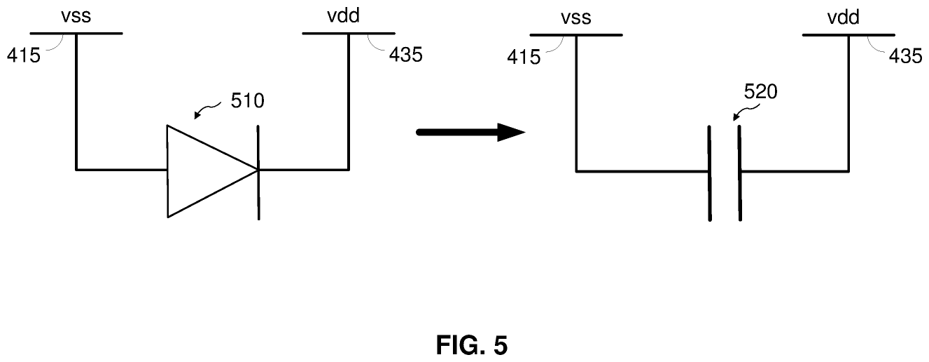

In this example, the p-substrate and the N-well between the n-type device 210 and the p-type device 310 form a diode, which is reversed bias since the n-type device 210 is coupled to the low rail 415 and the p-type device 310 is coupled to the power rail 435 (which is at a higher potential than the low rail 415). A circuit representation of the diode 510 is shown in FIG. 5. As shown in FIG. 5, the diode 510 is reversed biased between the power rail 435 and the low rail 415.

In this example, the capacitance of the diode 510 provides capacitance for the capacitor 410. In this regard, FIG. 5 also shows a capacitor 520 representing the capacitance of the diode 510. As shown in FIG. 5, the capacitor 520 is coupled between the power rail 435 and the low rail 415, and may therefore serve as a decoupling capacitor.

Aspects of the present disclosure provide new layout techniques for integrating a capacitor (e.g., decoupling capacitor) on the chip 100 using n-type devices and p-types devices. Layout techniques according to aspects of the present disclosure accommodate more n-type devices and p-types devices in a given area compared with current layout techniques, thereby increasing the capacitance for the given area. Also, layout techniques according to aspects of the present disclosure eliminate or reduce the number of poly over diffusion edge (PODE) devices compared with current layout techniques, thereby reducing leakage current caused by PODE devices. The above features and other features of the present disclosure are discussed further below.

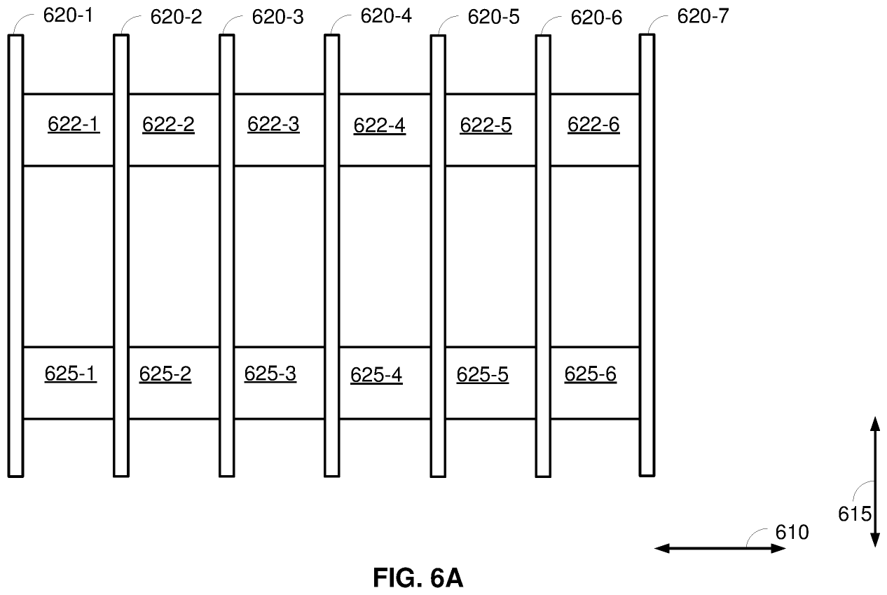

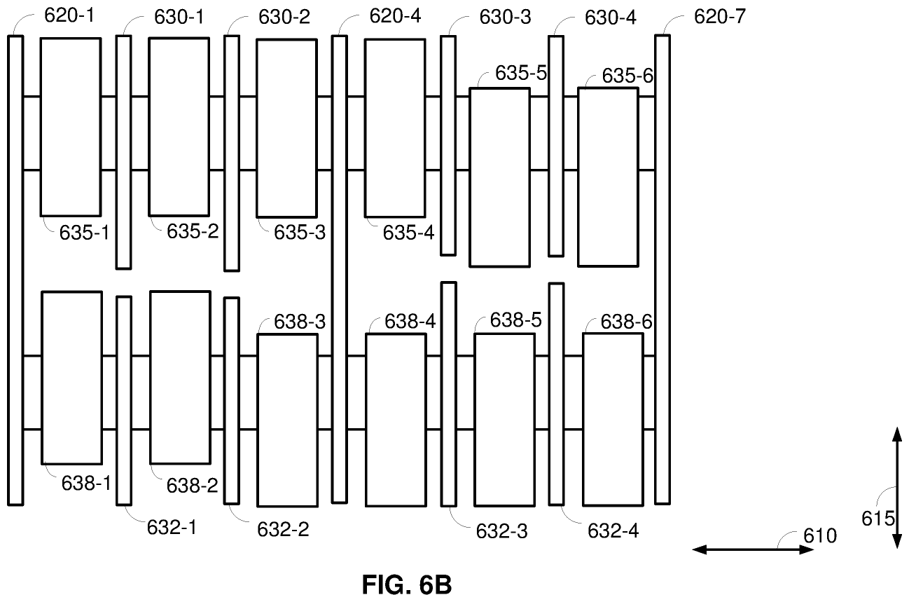

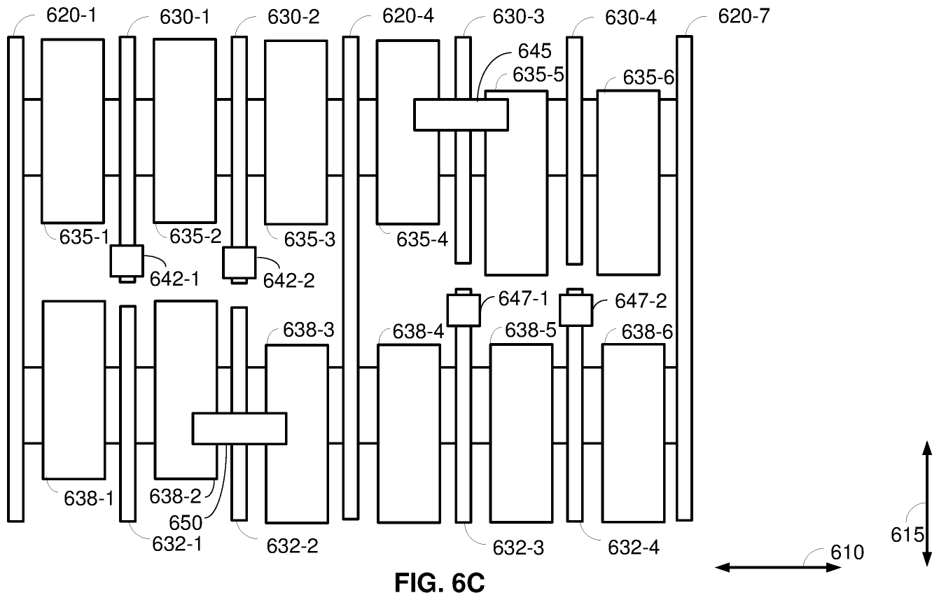

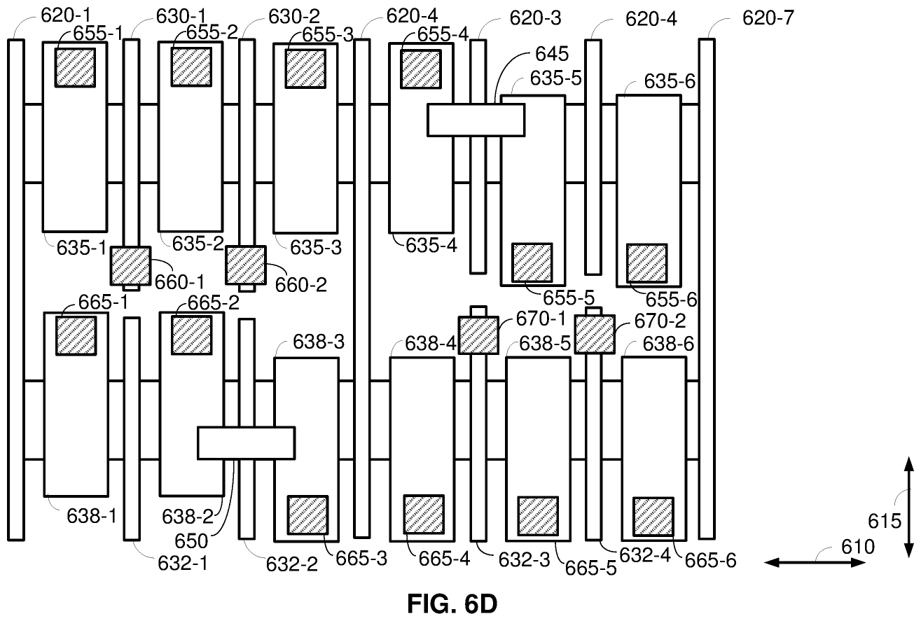

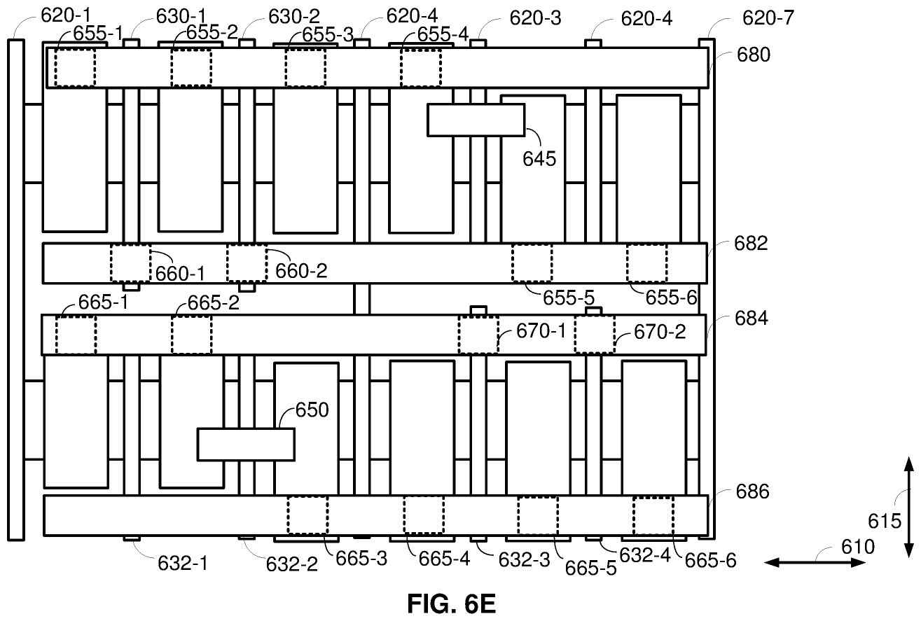

An exemplary layout for a capacitor (e.g., decoupling capacitor) will now be described with reference to FIGS. 6A to 6E according to certain aspects.

FIG. 6A shows a top view of a gate array including multiple gates 620-1 to 620-7 (e.g., poly gates), in which each of the gates 620-1 to 620-7 is elongated and extends in lateral direction 615. As used herein, a “lateral direction” is a direction that runs parallel with the substrate (e.g., p-substrate) of the chip 100. In the example in FIG. 6A, the gates 620-1 to 620-7 are uniformly spaced apart in lateral direction 610, in which lateral direction 610 is perpendicular to lateral direction 615. However, it is to be appreciated that the present disclosure is not limited to this example. In one example, the gate array corresponds to a cell, as discussed further below.

FIG. 6A also shows sources/drains 622-1 to 622-6 corresponding to a first oxide diffusion (OD), which may be a p-type OD. An OD may also be referred to as an active region, active diffusion, an active area, or another term. The sources/drains 622-1 to 622-6 may be p+ sources/drains that are formed using p+ diffusion, p+ implantation, or another process. In this example, each of the sources/drains 622-1 to 622-6 is between a respective pair of the gates 620-1 to 620-7.

FIG. 6A also shows sources/drains 625-1 to 625-6 corresponding to a second OD, which may be an n-type OD. The second OD is spaced apart from the first OD in lateral direction 615. The sources/drains 625-1 to 625-6 may be n+ sources/drains that are formed using n+ diffusion, n+ implantation, or another process. In this example, each of the sources/drains 625-1 to 625-6 is between a respective pair of the gates 620-1 to 620-7.

FIG. 6B shows an example in which gates 620-2, 620-3, 620-5, and 620-6 shown in FIG. 6A are cut between the first OD and the second OD. More particularly, gate 620-2 is cut into gates 630-1 and 632-1, gate 620-3 is cut into gates 630-2 and 632-2, gate 620-5 is cut into gates 630-3 and 632-3, and gate 620-6 is cut into gates 630-4 and 632-4. The gates 630-1 to 630-4 and 632-1 to 632-4 may be used as gates of devices. The gate 620-4 in the center may be a dummy gate.

FIG. 6B also shows an example of source/drain contacts 635-1 to 635-6, in which each of the source/drain contacts 635-1 to 635-6 is formed over a respective one of the sources/drains 622-1 to 622-6 shown in FIG. 6A. FIG. 6B also shows an example of source/drain contacts 638-1 to 638-6, in which each of the source/drain contacts 638-1 to 638-6 is formed over a respective one of the sources/drains 625-1 to 625-6 shown in FIG. 6A. The source/drain contacts 635-1 to 635-6 and 638-1 to 638-6 may be formed from the same contact layer (e.g., MD layer) using, for example, lithography and etching.

As shown in FIG. 6B, each of the gates 630-1 to 630-4 is disposed between a respective pair of the source/drain contacts 635-1 to 635-6, and each of the gates 632-1 to 632-4 is disposed between a respective pair of the source/drain contacts 638-1 to 638-6. Note that two pairs of source/drain contacts may have one source/drain in common. For example, gate 630-1 is between respective pair of source/drain contacts 635-1 and 635-2, and gate 630-2 is between respective pair of source/drain contacts 635-2 and 635-3, where source/drain contact 635-2 is common to both pairs.

FIG. 6C shows an example of gate contacts 642-1 and 642-2 formed on gates 630-1 and 630-2, respectively, and gate contacts 647-1 and 647-2 formed on gates 632-3 and 632-4, respectively. The gate contacts 642-1, 642-2, 647-1, and 647-2 may be formed from the gate contact layer (e.g., MP layer) using, for example, lithography and etching.

FIG. 6C also shows an example of a first bridge 645 extending in lateral direction 610 over the gate 630-3 and the source/drain contacts 635-4 and 635-5. The first bridge 645 may be formed from the gate contact layer (e.g., MP layer) using, for example, lithography and etching. In other words, in this example, the source/drain 622-4, the gate 630-3, and the source/drain 622-5 are coupled to one another through the first bridge 645 (i.e., tied to a same potential by the first bridge 645). In this example, the source/drain 622-4, the gate 630-3, and the source/drain 622-5 may form a first p-type device. As used herein, a “bridge” may be a conductor (e.g., formed from a contact layer) coupling one or more sources/drains to a gate.

FIG. 6C also shows an example of a second bridge 650 extending in lateral direction 610 over the gate 632-2 and the source/drain contacts 638-2 and 638-3. The second bridge 650 may be formed from the gate contact layer (e.g., MP layer) using, for example, lithography and etching. In other words, in this example, the source/drain 625-2, the gate 632-2, and the source/drain 625-3 are coupled to one another through the second bridge 650 (i.e., tied to a same potential by the second bridge 650). In this example, the source/drain 625-2, the gate 632-2, and the source/drain 625-3 may form a first n-type device.

In certain aspects, the first and second bridges 645 and 650 are formed from the gate contact layer (e.g., MP layer), which may be at the same level as the source/drain contact layer (e.g., MD layer). However, it is to be appreciated that the present disclosure is not limited to this example. The gate contact layer and the source/drain contact layer may be the same contact layer or different contact layers. In general, the first bridge 645 and the second bridge 650 are formed from a contact layer, e.g., using lithography and etching.

FIG. 6D shows an example of vias 655-1 to 655-6 disposed on the source/drain contacts 635-1 to 635-6, respectively. The vias 655-1 to 655-4 are aligned in lateral direction 610, and the vias 655-5 and 655-6 are aligned in lateral direction 610. The vias 655-1 to 655-4 are spaced apart from the vias 655-5 and 655-6 in lateral direction 615. FIG. 6D also shows vias 660-1 and 660-2 disposed on the gate contacts 642-1 and 642-2, respectively. The vias 660-1 and 660-2 are aligned with the vias 655-5 and 655-6 in lateral direction 610. The vias 655-1 to 655-6, 660-1, and 660-2 may be formed form a via layer, e.g., using lithography and etching.

FIG. 6D also shows an example of vias 665-1 to 665-6 disposed on the source/drain contacts 638-1 to 635-6, respectively. The vias 665-3 to 665-6 are aligned in lateral direction 610, and the vias 665-1 and 665-2 are aligned in lateral direction 610. The vias 665-3 to 665-6 are spaced apart from the vias 665-1 and 665-2 in lateral direction 615. FIG. 6D also shows vias 670-1 and 670-2 disposed on the gate contacts 647-1 and 647-2, respectively. The vias 670-1 and 670-2 are aligned with the vias 665-1 and 665-2 in lateral direction 610. The vias 665-1 to 665-6, 670-1, and 670-2 may be formed form a via layer, e.g., using lithography and etching.

FIG. 6E shows an example of a first metal routing 680, a second metal routing 682, a third metal routing 684, and a fourth metal routing 686. The metal routings 680, 682, 684, and 686 extend in lateral direction 610, and are spaced apart in lateral direction 615. In the example in FIG. 6E, each of the metal routings 680, 682, 684, and 686 is shown as a contiguous metal line. However, it is to be appreciated that the present disclosure is not limited to this example. In certain aspects, the metal routings 680, 682, 684, and 686 are formed from metal layer M0, e.g., using lithography and etching. Note that the reference numbers for the source/drain contacts 635-1 to 635-6 and 638-1 to 638-6 are not explicitly shown in FIG. 6E for ease of illustration. As used herein, a “routing” may be a conductive path formed from one of the metal layers 150.

In the example in FIG. 6E, the first metal routing 680 is coupled to the source/drain contacts 635-1 to 635-4 through the vias 655-1 to 655-4. In other words, each of the vias 655-1 to 655-4 is coupled between the respective one of the source/drain contacts 635-1 to 635-4 and the first metal routing 680. The vias 655-1 to 655-4 are shown with doted lines in FIG. 6E to indicate that the vias are below the first metal routing 680.

The second metal routing 682 is coupled to the source/drain contacts 635-5 and 635-6 through vias 655-5 and 655-6, and coupled to the gates 630-1 and 630-2 through the vias 660-1 and 660-2. In other words, each of the vias 655-5 and 655-6 is coupled between the respective one of the source/drain contacts 635-5 and 635-6 and the second metal routing 682, and each of the vias 660-1 and 660-2 is coupled between the respective gate 630-1 and 630-2 and the second metal routing 682. The vias 655-5, 655-6, 660-1, and 660-2 are shown with doted lines in FIG. 6E to indicate that the vias are below the second metal routing 682.

In this example, the first metal routing 680 and the second metal routing 682 are coupled through the first bridge 645, which couples the source/drain contact 635-4, the gate 630-3 and the source/drain contact 635-5 together. As a result, the first metal routing 680 and the second metal routing 682 are at approximately the same potential. This exemplary layout forms three p-type devices coupled to a common potential. In certain aspects, the first metal routing 680 and the second metal routing 682 may be coupled to the power rail 435 shown in FIG. 4. Thus, in this example, the layout forms three p-type devices coupled to the power rail 435.

In the example in FIG. 6E, the fourth metal routing 686 is coupled to the source/drain contacts 638-3 to 638-6 through the vias 665-3 to 665-6. In other words, each of the vias 665-3 to 665-6 is coupled between the respective one of the source/drain contacts 638-3 to 638-6 and the fourth metal routing 686. The vias 665-3 to 665-6 are shown with doted lines in FIG. 6E to indicate that the vias are below the fourth metal routing 686.

The third metal routing 684 is coupled to the source/drain contacts 638-1 and 638-2 through vias 665-1 and 665-2, and coupled to the gates 632-3 and 632-4 through the vias 670-1 and 670-2. In other words, each of the vias 665-1 and 665-2 is coupled between the respective one of the source/drain contacts 638-1 and 638-2 and the third metal routing 684, and each of the vias 670-1 and 670-2 is coupled between the respective gate 632-3 and 632-4 and the third metal routing 684. The vias 665-1, 665-2, 670-1, and 670-2 are shown with doted lines in FIG. 6E to indicate that the vias are below the third metal routing 684.

In this example, the third metal routing 684 and the fourth metal routing 686 are coupled through the second bridge 650, which couples the source/drain contact 638-2, the gate 632-2 and the source/drain contact 638-3 together. As a result, the third metal routing 684 and the fourth metal routing 686 are at approximately the same potential. This exemplary layout forms three n-type devices coupled to a common potential. In certain aspects, the third metal routing 684 and the fourth metal routing 686 may be coupled to the low rail 415 shown in FIG. 4. Thus, in this example, the layout forms three n-type devices coupled to the low rail 415 (which is at a lower potential than the power rail 435).

Thus, the exemplary layout shown in FIG. 6E forms three p-type devices coupled to the power rail 435 and three n-types devices coupled to the low rail 415. The p-type devices and the n-type devices form a reversed biased diode (e.g., diode 510) between the power rail 435 and the low rail 415, in which the capacitance of the diode provides a decoupling capacitor between the power rail 435 and the low rail 415.

It is to be appreciated that the number of gates and the number of source/drain contacts shown in FIG. 6E are exemplary only, and that the layout techniques according to aspects of the present disclosure are not limited to a particular number of gates and a particular number of source/drain contacts.

The exemplary layout shown in FIG. 6E may used to define a decoupling capacitor cell (also referred to as a decap cell) in a standard cell library. In the layout of the chip 100, the decap cell may be inserted throughout a power delivery network to provide decoupling capacitors throughout the power deliver network. Other implementations of the decoupling capacitor cell may include different numbers of p-type devices and/or n-type devices.

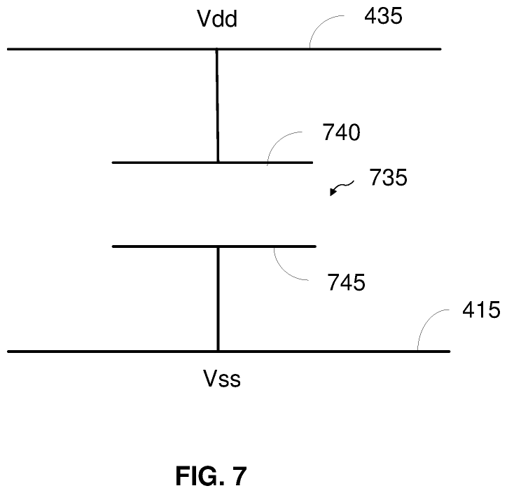

FIG. 7 shows a circuit diagram of an example of a decoupling capacitor 735 that may be implemented with the exemplary layout shown in FIG. 6E. One terminal 740 of the decoupling capacitor 735 is coupled to the power rail 435 (also referred to as a supply voltage rail) providing the supply voltage Vdd, and another terminal 745 of the decoupling capacitor 735 is coupled to the low rail 415, which is at a lower potential than the power rail 435. For example, the low rail 415 may be a ground rail coupled to ground, but is not limited to this example. The terminal 740 may correspond to the first and second metal routings 680 and 682 shown in FIG. 6E, which are coupled to the power rail 435 in this example. The terminal 745 may correspond to the third and fourth metal routings 684 and 686 shown in FIG. 6E, which are coupled to the low rail 415 in this example.

Implementation examples are described in the following numbered clauses:]

1. A chip, comprising:
first source/drain contacts formed over a first oxide diffusion (OD);
first gates, wherein each of the first gates is disposed between a respective pair of the first source/drain contacts;
a first bridge coupling a first one of the first source/drain contacts, a first one of the first gates, and a second one of the first source/drain contacts;
a first metal routing coupled to the first one of the first source/drain contacts; and
a second metal routing coupled to the second one of the first source/drain contacts.

2. The chip of clause 1, wherein the first OD is a p-type OD, and the first metal routing and the second metal routing are coupled to a power rail.

3. The chip of clause 1 or 2, wherein the first metal routing is coupled to a third one of the first source/drain contacts, and the second metal routing is coupled to a second one of the first gates.

4. The chip of clause 3, wherein the first metal routing is coupled to a fourth one of the first source/drain contacts, and the second metal routing is coupled to a third one of the first gates.

5. The chip of any one of clauses 1 to 4, wherein each of the first gates extends in a first direction, and each of the first metal routing and the second metal routing extends in a second direction that is perpendicular to the first direction.

6. The chip of any one of clauses 1 to 5, wherein the first bridge is formed from a contact layer.

7. The chip of clause 6, wherein the contact layer is a gate contact layer.

8. The chip of clause 6 or 7, wherein each of the first metal routing and the second metal routing is formed from a M0 metal layer or an M1 metal layer.

9. The chip of any one of clauses 1 to 8, further comprising:
second source/drain contacts formed over a second OD;
second gates, wherein each of the second gates is disposed between a respective pair of the second source/drain contacts;
a second bridge coupling a first one of the second source/drain contacts, a first one of the second gates, and a second one of the second source/drain contacts;
a third metal routing coupled to the first one of the second source/drain contacts; and
a fourth metal routing coupled to the second one of the second source/drain contacts.

10. The chip of clause 9, wherein the first OD is a p-type OD, and the first metal routing and the second metal routing are coupled to a power rail.

11. The chip of clause 10, wherein the second OD is a n-type OD, the third metal routing and the fourth metal routing are coupled to a low rail, and the low rail has a lower potential than the power rail.

12. The chip of clause 11, wherein the low rail is coupled to a ground.

13. The chip of any one of clauses 9 to 12, wherein the first metal routing is coupled to a third one of the first source/drain contacts, and the second metal routing is coupled to a second one of the first gates.

14. The chip of clause 13, wherein the third metal routing is coupled to a third one of the second source/drain contacts, and the fourth metal routing is coupled to a second one of the second gates.

15. The chip of any one of clauses 9 to 14, wherein each of the first gates and the second gates extends in a first direction, and each of the first metal routing, second metal routing, the third metal routing, and the fourth metal routing extends in a second direction that is perpendicular to the first direction.

16. The chip of any one of clauses 9 to 15, wherein each of the first bridge and the second bridge is formed from a contact layer.

17. The chip of clause 16, wherein the contact layer is a gate contact layer.

18. The chip of clause 16 or 17, wherein each of the first metal routing, the second metal routing, the third metal routing, and the fourth metal routing is formed from a M0 metal layer or an M1 metal layer.

19. A chip, comprising:
a power rail;
a low rail, the low rail having a lower potential than the power rail; and
a decoupling capacitor coupled between the power rail and the low rail, the decoupling capacitor comprising:
   first source/drain contacts formed over a first oxide diffusion (OD);
   first gates, wherein each of the first gates is disposed between a respective pair of the first source/drain contacts;
   a first bridge coupling a first one of the first source/drain contacts, a first one of the first gates, and a second one of the first source/drain contacts;
   a first metal routing coupled to the first one of the first source/drain contacts; and
   a second metal routing coupled to the second one of the first source/drain contacts, wherein the first metal routing and the second routing are coupled to the power rail.

20. The chip of clause 19, wherein the decoupling capacitor further comprises:
second source/drain contacts formed over a second OD;
second gates, wherein each of the second gates is disposed between a respective pair of the second source/drain contacts;
a second bridge coupling a first one of the second source/drain contacts, a first one of the second gates, and a second one of the second source/drain contacts;
a third metal routing coupled to the first one of the second source/drain contacts; and
a fourth metal routing coupled to the second one of the second source/drain contacts, wherein the third metal routing and the fourth metal routing are coupled to the low rail.

21. The chip of clause 20, wherein the first OD is a p-type OD, and the second OD is a n-type OD.

22. The chip of clause 20 or 21, wherein the first metal routing is coupled to a third one of the first source/drain contacts, and the second metal routing is coupled to a second one of the first gates.

23. The chip of clause 22, wherein the third metal routing is coupled to a third one of the second source/drain contacts, and the fourth metal routing is coupled to a second one of the second gates.

24. The chip of any one of clauses 20 to 23, wherein each of the first bridge and the second bridge is formed from a contact layer.

25. The chip of clause 24, wherein the contact layer is a gate contact layer.

26. The chip of any one of clauses 20 to 25, wherein each of the first metal routing, the second metal routing, the third metal routing, and the fourth metal routing is formed from a M0 metal layer or a M1 metal layer.

27. The chip of any one of clauses 19 to 26, wherein the low rail is coupled to a ground.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
first source/drain contacts formed over a first oxide diffusion (OD);
first gates, wherein each of the first gates is disposed between a respective pair of the first source/drain contacts;
a first bridge coupling a first one of the first source/drain contacts, a first one of the first gates, and a second one of the first source/drain contacts;
a first metal routing coupled to the first one of the first source/drain contacts; and
a second metal routing coupled to the second one of the first source/drain contacts.

2. The chip of claim 1, wherein the first OD is a p-type OD, and the first metal routing and the second metal routing are coupled to a power rail.

3. The chip of claim 1, wherein the first metal routing is coupled to a third one of the first source/drain contacts, and the second metal routing is coupled to a second one of the first gates.

4. The chip of claim 3, wherein the first metal routing is coupled to a fourth one of the first source/drain contacts, and the second metal routing is coupled to a third one of the first gates.

5. The chip of claim 1, wherein each of the first gates extends in a first direction, and each of the first metal routing and the second metal routing extends in a second direction that is perpendicular to the first direction.

6. The chip of claim 1, wherein the first bridge is formed from a contact layer.

7. The chip of claim 6, wherein the contact layer is a gate contact layer.

8. The chip of claim 6, wherein each of the first metal routing and the second metal routing is formed from a M0 metal layer or an M1 metal layer.

9. The chip of claim 1, further comprising:
second source/drain contacts formed over a second OD;
second gates, wherein each of the second gates is disposed between a respective pair of the second source/drain contacts;
a second bridge coupling a first one of the second source/drain contacts, a first one of the second gates, and a second one of the second source/drain contacts;
a third metal routing coupled to the first one of the second source/drain contacts; and
a fourth metal routing coupled to the second one of the second source/drain contacts.

10. The chip of claim 9, wherein the first OD is a p-type OD, and the first metal routing and the second metal routing are coupled to a power rail.

11. The chip of claim 10, wherein the second OD is a n-type OD, the third metal routing and the fourth metal routing are coupled to a low rail, and the low rail has a lower potential than the power rail.

12. The chip of claim 11, wherein the low rail is coupled to a ground.

13. The chip of claim 9, wherein the first metal routing is coupled to a third one of the first source/drain contacts, and the second metal routing is coupled to a second one of the first gates.

14. The chip of claim 13, wherein the third metal routing is coupled to a third one of the second source/drain contacts, and the fourth metal routing is coupled to a second one of the second gates.

15. The chip of claim 9, wherein each of the first gates and the second gates extends in a first direction, and each of the first metal routing, second metal routing, the third metal routing, and the fourth metal routing extends in a second direction that is perpendicular to the first direction.

16. The chip of claim 9, wherein each of the first bridge and the second bridge is formed from a contact layer.

17. The chip of claim 16, wherein the contact layer is a gate contact layer.

18. The chip of claim 16, wherein each of the first metal routing, the second metal routing, the third metal routing, and the fourth metal routing is formed from a M0 metal layer or an M1 metal layer.

19. A chip, comprising:
a power rail;
a low rail, the low rail having a lower potential than the power rail; and
a decoupling capacitor coupled between the power rail and the low rail, the decoupling capacitor comprising:
first source/drain contacts formed over a first oxide diffusion (OD);
first gates, wherein each of the first gates is disposed between a respective pair of the first source/drain contacts;
a first bridge coupling a first one of the first source/drain contacts, a first one of the first gates, and a second one of the first source/drain contacts;
a first metal routing coupled to the first one of the first source/drain contacts; and
a second metal routing coupled to the second one of the first source/drain contacts, wherein the first metal routing and the second routing are coupled to the power rail.

20. The chip of claim 19, wherein the decoupling capacitor further comprises:
second source/drain contacts formed over a second OD;
second gates, wherein each of the second gates is disposed between a respective pair of the second source/drain contacts;
a second bridge coupling a first one of the second source/drain contacts, a first one of the second gates, and a second one of the second source/drain contacts;
a third metal routing coupled to the first one of the second source/drain contacts; and
a fourth metal routing coupled to the second one of the second source/drain contacts, wherein the third metal routing and the fourth metal routing are coupled to the low rail.

21. The chip of claim 20, wherein the first OD is a p-type OD, and the second OD is a n-type OD.

22. The chip of claim 20, wherein the first metal routing is coupled to a third one of the first source/drain contacts, and the second metal routing is coupled to a second one of the first gates.

23. The chip of claim 22, wherein the third metal routing is coupled to a third one of the second source/drain contacts, and the fourth metal routing is coupled to a second one of the second gates.

24. The chip of claim 20, wherein each of the first bridge and the second bridge is formed from a contact layer.

25. The chip of claim 24, wherein the contact layer is a gate contact layer.

26. The chip of claim 20, wherein each of the first metal routing, the second metal routing, the third metal routing, and the fourth metal routing is formed from a M0 metal layer or a M1 metal layer.

27. The chip of claim 19, wherein the low rail is coupled to a ground.
